(19) United States
(12) Patent Application Publication
(10) Pub. No.: US 2025/0176336 A1
(43) Pub. Date: May 29, 2025

(54) DISPLAY PANEL, METHOD FOR MANUFACTURING DISPLAY PANEL, AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Xiaoxi SUN, Hefei (CN); Yuan YAO, Hefei (CN); Xuejing ZHU, Hefei (CN); Bo RAO, Hefei (CN); Fa-Hsyang CHEN, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/754,876

(22) Filed: Jun. 26, 2024

(30) Foreign Application Priority Data
Nov. 24, 2023 (CN) 202311596673.3
Jun. 11, 2024 (CN) 202410752415.8

(51) Int. Cl. H01L 33/62; H01L 25/075; H01L 33/54

(52) U.S. Cl. CPC H10H 20/857; H01L 25/0753; H10H 20/853; H10H 20/0364

(57) ABSTRACT

A display panel, a method for manufacturing a display panel, and a display apparatus. The display panel includes a display area and a non-display area arranged surrounding at least a portion of the display area. The display panel further includes: a substrate; an isolation structure formed at one side of the substrate and including a first portion located in the display area and a second portion located in the non-display area, the first portion encircling a first opening, and the second portion encircling a second opening; a light-emitting unit formed at one side of the substrate and located in the first opening; a shielding layer at least partially formed in the second opening and electrically connected to the second portion; and an electrically conductive layer formed at a side of the shielding layer, the light-emitting unit, and the isolation structure being away from the substrate.

### CROSS REFERENCE TO RELATED APPLICATION

The present application claims priority to Chinese Patent Application No. 202311596673.3 filed on Nov. 24, 2023 and Chinese Patent Application No 202410752415.8 filed on Jun. 11, 2024, both of which are incorporated herein by reference in their entireties.

### TECHNICAL FIELD

The present application relates to the field of display technology, and particularly to a display panel, a method for manufacturing a display panel, and a display apparatus.

### BACKGROUND

With the development of display technology, the demand for the performance of display devices becomes higher and higher. AMOLED is more and more widely used and influential due to its excellent color saturation and image quality. However, the existing display devices are prone to interference between signals at the frame, which seriously degrades the performance of the display devices.

### SUMMARY

Embodiments of the present application provide a display panel, a method for manufacturing a display panel, and a display apparatus, which can reduce mutual interference between a signal within the electrically conductive layer and a signal within a signal line in the substrate, so as to improve the yield of the display panel.

Embodiments of a first aspect of the embodiments of the present application provide a display panel having a display area and a non-display area arranged surrounding at least a portion of the display area, the display panel including: a substrate; an isolation structure formed at one side of the substrate and including a first portion located in the display area and a second portion located in the non-display area, the first portion encircling a first opening, and the second portion encircling a second opening; a light-emitting unit formed at one side of the substrate and located in the first opening; a shielding layer at least partially formed in the second opening and electrically connected to the second portion; and an electrically conductive layer formed at a side of the shielding layer, the light-emitting unit, and the isolation structure being away from the substrate.

Embodiments of a second aspect of the present application provide a method for manufacturing a display panel having a display area and a non-display area arranged surrounding at least a portion of the display area, the method including: providing a substrate; forming an isolation structure at one side of the substrate, the isolation structure including a first portion located in the display area and a second portion located in the non-display area, the first portion encircling a first opening, and the second portion encircling a second opening; forming a light-emitting unit within the first opening; forming a shielding layer at a side of the isolation structure away from the substrate, at least a portion of the shielding layer being formed in the second opening and electrically connected to the second portion; and forming an electrically conductive layer at a side of the shielding layer, the light-emitting unit, and the isolation structure away from the substrate.

Embodiments of a third aspect of the present application provide a display panel having a display area and a non-display area arranged surrounding at least a portion of the display area, the display panel including: a substrate including a circuit structure; a light-emitting unit formed at one side of the substrate and located in the display area; an electrically conductive layer formed at a side of the light-emitting unit away from the substrate; and a shielding structure arranged between the electrically conductive layer and the circuit structure of the substrate and at least partially located in the non-display area, and an orthographic projection of the shielding structure on the substrate covering an orthographic projection of the electrically conductive layer on the substrate.

The display panel according to present application includes the display area and the non-display area. The display panel includes the substrate, the isolation structure, the light-emitting unit, the shielding layer, and the electrically conductive layer. The isolation structure is formed at one side of the substrate and includes the first portion located in the display area and the second portion located in the non-display area, the first portion encircles the first opening, the second portion encircles the second opening, the first opening is configured to accommodate the light-emitting unit, and the first opening can prevent the isolation structure from shielding the light emitted by the light-emitting unit. At least a portion of the shielding layer is formed in the second opening and electrically connected to the second portion. Accordingly, the second portion and the shielding layer in the non-display area may form a continuous film layer, so as to achieve mutual shielding between a portion of the electrically conductive layer located in the non-display area and a signal line in the substrate located in the non-display area, and reduce mutual interference between a signal within the portion of the electrically conductive layer located in the non-display area and a signal within the signal line in the substrate, so that the yield of the display panel is improved.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 shows a schematic structural diagram of a display panel according to the embodiments of the present application;

FIG. 2 shows a cross-sectional diagram along P-P′ in FIG. 1;

FIG. 3 shows a schematic structural diagram of an electrically conductive layer of a display panel according to the embodiments of the present application;

FIG. 4 shows another cross-sectional diagram along P-P′ in FIG. 1;

FIG. 5 shows a schematic structural diagram of a second opening in an isolation structure of a display panel according to the embodiments of the present application;

FIG. 6 shows an enlarged diagram of area Q in FIG. 5;

FIG. 7 shows a schematic structural diagram of a second opening in an isolation structure of another display panel according to the embodiments of the present application;

FIG. 8 shows an enlarged diagram of area M in FIG. 7;

FIG. 9 shows a schematic structural diagram of a display apparatus according to the embodiments of the present application;

FIG. 10 shows a flowchart of a method for manufacturing a display panel according to the embodiments of the present application.

### REFERENCE NUMERALS

1: display panel; AA: display area; NA: non-display area; 11: substrate; 111: signal line; 12: isolation structure; 121: first portion; 1211: first opening; 122: second portion; 1221: second opening; 123: first isolation portion; 124: second isolation portion; 13: light-emitting unit; 131: first electrode; 132: light-emitting functional layer; 1320: light-emitting material layer; 1321: first section; 1322: second section; 133: second electrode; 14: shielding layer; 141: first sub-portion; 142: second sub-portion; 15: electrically conductive layer; 151: touch control wiring; 1510: wiring segment; 152: touch control electrode; 1521: first touch control electrode; 1522: second touch control electrode; 153: connection line; 1531: first connection line; 1532: second connection line; NA1: levelling area; NA2: blocking area; 18: dam; 16: encapsulation layer; 161: first encapsulation layer; 162: second encapsulation layer; 163: third encapsulation layer; 17: pixel definition layer; 171: pixel definition portion; 172: pixel opening; 2: display apparatus.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

The inventors have found that the reason why the display devices are prone to interference between signals at the frame is that: in the existing display panel, there is no metal layer as a shielding barrier between the touch control wiring of the touch control layer in the non-display area and the signal line in the substrate, and thus the touch control wiring of the touch control layer in the non-display area and the signal line in the substrate are likely to interfere with each other. Based on the study on the above problems, the inventors provided a display panel, a method for manufacturing a display panel, and a display apparatus to reduce the signal interference in the non-display area.

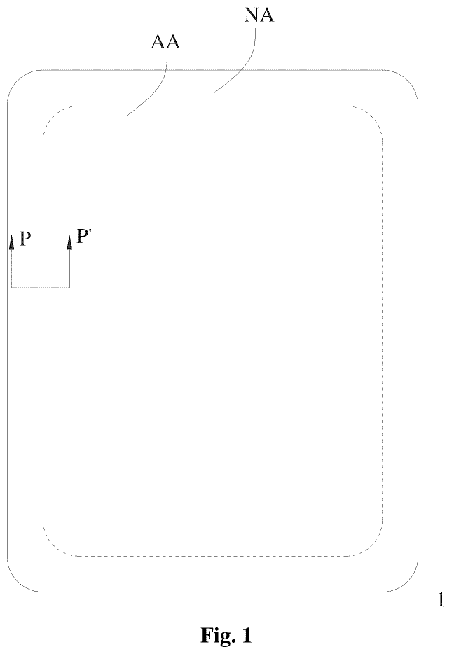

For a better understanding of the present application, a display panel, a method for manufacturing a display panel, and a display apparatus according to the embodiments of the present application will be described in detail below with reference to FIG. 1 to FIG. 10.

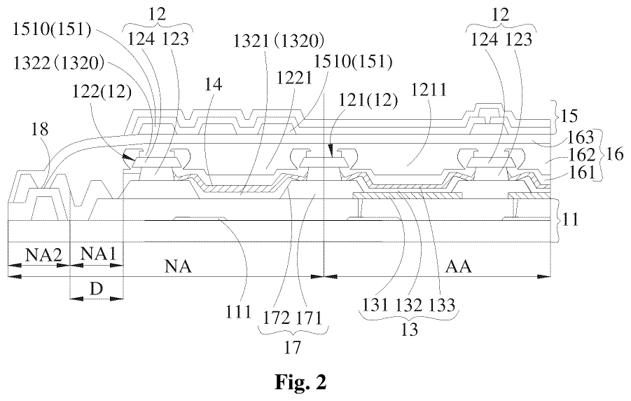

Referring to FIG. 1 and FIG. 2, the embodiments of the present application provide a display panel 1 having a display area AA and a non-display area NA arranged surrounding at least a portion of the display area AA. The display panel 1 includes a substrate 11, a light-emitting unit 13, a shielding structure, and an electrically conductive layer 15.

The light-emitting unit 13 is formed at one side of the substrate 11 and located in the display area AA, and the electrically conductive layer 15 is formed at a side of the light-emitting unit 13 away from the substrate 11. The shielding structure is arranged between the electrically conductive layer 15 and the substrate 11 and at least parti ally located in the non-display area NA, and an orthographic projection of the shielding structure on the substrate 11 overlaps an orthographic projection of the electrically conductive layer 15 on the substrate 11.

The display panel 1 according to the present application includes the display area AA and the non-display area NA, the display area AA is an area in the display panel 1 configured to achieve display function, the non-display area NA is arranged surrounding the periphery of the display area AA, and structures such as a driving chip and a driving circuit may be arranged in the non-display area NA.

The display panel 1 includes the substrate 11, and the light-emitting unit 13, the shielding structure, the electrically conductive layer 15, and other film layers or device structures are formed at the same side of the substrate 11. Herein, the substrate 11 may include a plurality of stacked film layer structures, and specific film layer arrangements in the substrate 11 are not limited in the embodiments of the present application. For example, the substrate 11 may be provided with a plurality of conductor layers and semiconductor layers and insulating layers located between adjacent conductor layer and semiconductor layer, a conductor structure is arranged in the conductor layer, and an active structure is arranged in the semiconductor layer. Further, the substrate includes a circuit structure, and the circuit structure may include a pixel circuit in the display area and a scanning circuit in the non-display area, or other types of circuits, which is not limited in the embodiments of the present application.

A thin film transistor may be arranged in the substrate 11 and constitutes a pixel circuit driving the light-emitting unit 13 to emit light, and the thin film transistor includes a conductor structure located within a portion of the conductor layer and an active structure located within the semiconductor layer.

In the related art, a portion of the electrically conductive layer 15 and some conductor structure (such as a signal line 111) in the substrate 11 are arranged opposite to each other in the non-display area NA, causing mutual interference between the electrically conductive layer 15 and the substrate 11. In view of this, in the embodiments of the present application, the shielding structure is added in the display panel 1, the shielding structure is arranged between the electrically conductive layer 15 and the substrate 11 and at least partially located in the non-display area NA, and the shielding structure may provide signal shielding between the portion of the electrically conductive layer 15 and the signal line 111 in the substrate 11 that are located within the non-display area NA, so that the risk of signal interference is reduced, thereby protecting the conductor structure within the substrate 11 and the electrically conductive layer 15, and improving the yield and usage reliability of the display panel 1. Herein, the signal line 111 may be a portion of the circuit structure and may be used as a scanning signal line in the non-display area.

It should be noted that, the specific type of the electrically conductive layer 15 is not limited in the embodiments of the present application. Optionally, a structure within the electrically conductive layer 15 may be configured to transmit a touch control signal or other signals, as long as the electrically conductive layer 15 is located at a side of the light-emitting unit 13 away from the substrate 11.

In some embodiments, the shielding structure includes an isolation structure 12 formed at one side of the substrate, the isolation structure 12 includes a first portion 121 located in the display area AA and a second portion 122 located in the non-display area NA, the first portion 121 encircles s a first opening 1211, and the light-emitting unit 13 is located in the first opening 1211. An orthographic projection of the second portion 122 on the substrate 11 overlaps an orthographic projection of the electrically conductive layer 15 on the substrate 11.

The isolation structure 12 is formed at one side of the substrate 11 and includes the first portion 121 located in the display area AA and the second portion 122 located in the non-display area NA, the first portion 121 encircles the first opening 1211, the second portion 122 encircles the second opening 1221, the first opening 1211 is configured to accommodate the light-emitting unit 13, and the first opening 1211 can prevent the isolation structure 12 from shielding the light emitted by the light-emitting unit 13.

In the embodiments of the present application, the second portion 122 in the isolation structure 12 is located within the non-display area NA, and the orthographic projection of the second portion 122 on the substrate 11 overlaps the orthographic projection of the electrically conductive layer 15 on the substrate 11. With such design, the second portion 122 can achieve mutual shielding between a portion of the electrically conductive layer 15 located in the non-display area NA and the signal line 111 in the substrate 11 located within the non-display area NA, and reduce mutual interference between a signal within the portion of the electrically conductive layer 15 located in the non-display area NA and a signal within the signal line 111, so that the usage reliability of the display panel 1 is improved.

Moreover, optionally, within the non-display area NA, the orthographic projection of the second portion 122 on the substrate 11 completely covers the orthographic projection of the electrically conductive layer 15 on the substrate 11.

In the embodiments of the present application, the size and shape of the second portion 122 depends on the portion of the electrically conductive layer 15 located in the non-display area NA, and by adjusting the size and shape of the second portion 122, the orthographic projection of the second portion 122 on the substrate 11 completely covers the orthographic projection of the electrically conductive layer 15 on the substrate 11, so that the shielding effect of the second portion 122 between the portion of the electrically conductive layer 15 located in the non-display area NA and the signal line 111 in the substrate 11 located within the non-display area NA is improved.

Optionally, the first portion and the second portion of the isolation structure may be not exactly the same, as along as at least a portion of film layers of the first portion and at least a portion of film layers of the second portion have a same material and are manufactured in a same layer. For example, the isolation structure includes a first layer and a second layer which are stacked, and only the first layers or the second layers of the first portion and the second portion may be the same, so that the manufacturing process can be simplified and t the shielded structure can be manufactured using the existing processes.

Alternatively, the first portion and the second portion may be arranged as being exactly the same, which is not limited in the present application.

The second portion may be a whole surface structure in the non-display area and arranged surrounding the display area, so that the shielding structure can be formed all around the display area, thereby avoiding mutual interference between the electrically conductive layer and the circuit structure.

The second portion being a whole surface structure means that no second opening is arranged in the second portion, i.e., at least a portion of the film layer structure is not provided with the second opening in the non-display area.

In some embodiments, the light-emitting unit 13 may include a first electrode 131, a light-emitting functional layer 132, and a second electrode 133 stacked along a direction away from the substrate 11, and the shielding structure includes a shielding layer 14 manufactured in the same layer as the second electrode 133.

The shielding layer 14 is manufactured in the same layer as the second electrode 133, that is, the shielding layer 14 and the second electrode 133 are located in the same film layer, and further, both the shielding layer 14 and the second electrode 133 may be manufactured together in the same process, so that both the shielding layer 14 and the second electrode 133 may include the same electrically conductive material.

In other embodiments, the shielding layer 14 is manufactured in the same layer as the first electrode 131, that is, the shielding layer 14 and the first electrode 131 are located in the same film layer, and further, both the shielding layer 14 and the first electrode 131 may be manufactured together in the same process, so that both the shielding layer 14 and the first electrode 131 may include the same electrically conductive material.

The second electrode 133 is located within the display area AA and configured to drive, collectively with the first electrode 131, the light-emitting functional layer 132 to emit light, thereby meeting display requirements of the display panel 1. The shielding layer 14 is manufactured in the same layer as the second electrode 133 and arranged within the non-display area NA, and the shielding layer 14 can achieve mutual shielding between the portion of the electrically conductive layer 15 located in the non-display area NA and the signal line 111 in the substrate 11 located within the non-display area NA, and reduce mutual interference between the signal within the portion of the electrically conductive layer 15 located in the non-display area NA and the signal within the some conductor structure within the substrate 11, so that the usage reliability of the display panel 1 is improved.

In some optional embodiments, an orthographic projection of the shielding layer 14 on the substrate 11 overlaps the orthographic projection of the electrically conductive layer 15 on the substrate 11. Moreover, optionally, within the non-display area NA, the orthographic projection of the shielding layer 14 on the substrate 11 completely covers the orthographic projection of the electrically conductive layer 15 on the substrate 11.

In the embodiments of the present application, the size and shape of the shielding layer 14 depends on the portion of the electrically conductive layer 15 located in the non-display area NA, and by adjusting the size and shape of the shielding layer 14, the orthographic projection of the shielding layer 14 on the substrate 11 completely covers the orthographic projection of the electrically conductive layer 15 on the substrate 11, so that the shielding effect of the shielding layer 14 between the portion of the electrically conductive layer 15 located in the non-display area NA and the signal line 111 in the substrate 11 located within the non-display area NA is improved.

In some embodiments, the shielding structure includes an isolation structure 12 and a shielding layer 14 formed at one side of the substrate 11, the isolation structure 12 includes a first portion 121 located in the display area AA and a second portion 122 located in the non-display area NA, the first portion 121 encircles a first opening 1211, and the second portion 122 encircles a second opening 1221. The light-emitting unit 13 is located in the first opening 1211, the shielding layer 14 includes a first sub-portion 141 located in the second opening 1221, and the first sub-portion 141 is electrically connected to the second portion 122.

The isolation structure 12 includes the first portion 121 located in the display area AA and the second portion 122 located in the non-display area NA, and the first portion 121 and the second portion 122 encircle the first opening 1211 and the second opening 1221, respectively. At least one light-emitting unit 13 may be formed in each first opening 1211, and the second electrode 133 of the light-emitting unit 13 may be electrically connected to the first portion 121, so that the second electrodes 133 can be powered up synchronously.

At least a portion of the shielding layer 14 is formed in the second opening 1221 and electrically connected to the second portion 122. Accordingly, the second portion 122 and the shielding layer 14 in the non-display area NA may form a continuous film layer, so as to achieve mutual shielding between the portion of the electrically conductive layer 15 located in the non-display area NA and the signal line 111 in the substrate 11 located within the non-display area NA, and reduce mutual interference between the signal within the portion of the electrically conductive layer 15 located in the non-display area NA and the signal within the signal line 111 of the substrate 11, so that the yield of the display panel 1 is improved.

Moreover, the second portion 122 in the non-display area NA encircles the second opening 1221, and at least a portion of the shielding layer 14 is located in the second opening 1221, and thus the shielding layer 14 and the isolation structure 12 can be arranged alternately along a direction parallel to the substrate 11, so as to reduce the peeling of a large area of metal after being in contact with the underlying film layer and prevent static electricity to protect the signal line 111 within the substrate 11, otherwise the static electricity may cause blackening, breakdown, and breaking-off of the signal line 111 within the substrate 11, causing open circuit and short circuit.

Further, the first portion 121 and the second portion 122 of the isolation structure 12 may be connected, so that the first portion 121 and the second portion 122 can be powered up synchronously. The second portion 122 and the shielding layer 14 can be powered up synchronously and the first portion 121 and the second electrode 133 can be powered up synchronously by supplying direct current to the isolation structure 12, and the supplying of direct current within the second portion 122 and the shielding layer 14 can achieve good shielding effect.

Specifically, the first portion 121 and the second portion 122 may be patterned synchronously to form a mesh structure, and the first portion 121 and the second portion 122 may form a one-piece structure.

Specifically, an orthographic projection of the first sub-portion 141 on the second opening 1221 may cover the second opening 1221, so that the location between the second openings 1221 may be shielded by the second portion 122, and the location within the second opening 1221 may be shielded by the first sub-portion 141, so as to achieve sealed shielding effect.

Furthermore, in some embodiments, the shielding layer 14 further includes, in addition to the first sub-portion 141, a second sub-portion 142 located at a side of the second portion 122 away from the substrate 11. That is, in the manufacturing process of the shielding layer 14, a portion of the material will fall into the second opening 1221 to form the first sub-portion 141, and a portion of the material will fall at a side of the second portion 122 away from the substrate 11 to form the second sub-portion 142.

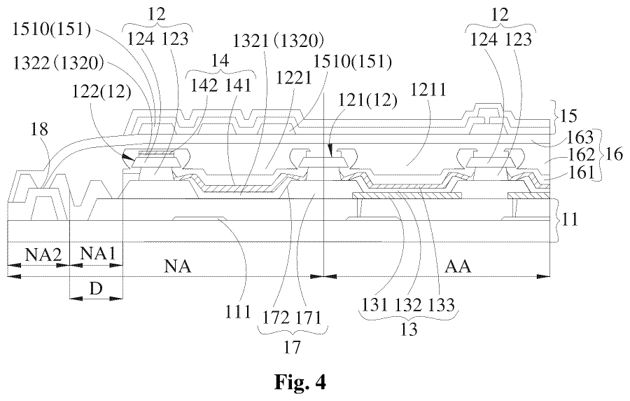

In a possible implementation, as shown in FIG. 4, the light-emitting unit 13 includes a first electrode 131, a light-emitting functional layer 132, and a second electrode 133 stacked along a direction away from the substrate 11, and the shielding layer 14 is manufactured in the same layer as the second electrode 133.

In the above implementation, the shielding layer 14 and the second electrode 133 may be manufactured simultaneously, that is, the second electrode 133 and the shielding layer 14 are manufactured using the same material and in the same process, so that no additional manufacturing step is added, the manufacturing process of the display panel 1 can be simplified, and the manufacturing cost can be reduced. The shielding layer 14 may form, in the manufacturing process, the first sub-portion 141 located within the second opening 1221 and the second sub-portion 142 located at a side of a second section 1322 away from the second portion 122, and the first sub-portion 141 is electrically connected to the second portion 122 and covers the second opening 1221, thereby forming a sealed whole layer by the second portion 122 and the first sub-portion 141 to improve the shielding effect.

In a possible implementation, as shown in FIG. 2, the display panel 1 further includes a light-emitting material layer 1320, the light-emitting material layer 1320 is arranged in the same layer as at least a portion of the light-emitting functional layer 132 and includes a first section 1321 located in the second opening 1221 and a second section 1322 located at a side of the second portion 122 away from the substrate 11.

In the above implementation, the light-emitting material layer 1320 and the light-emitting functional layer 132 are arranged in the same layer and may be manufactured using the same manufacturing process. The light-emitting material layer 1320 includes the first section 1321 located in the second opening 1221 and the second section 1322 located at the side of the second portion 122 away from the substrate 11.

In a possible implementation, as shown in FIG. 2 and FIG. 4, the non-display area NA further includes a levelling area NA1 located at a side of the second portion 122 away from the display area AA, the display panel 1 further includes an encapsulation layer 16 located at a side of the shielding layer 14 and the light-emitting unit 13 away from the substrate 11 and between the substrate 11 and the electrically conductive layer 15, and along a direction perpendicular to a plane where the substrate 11 is located, a thickness of a portion of the encapsulation layer 16 within the levelling area NA1 is less than a thickness of a portion of the encapsulation layer 16 located within the display area AA and less than a thickness of a portion of the encapsulation layer 16 located between the levelling area NA1 and the display area AA.

In the above implementation, the display panel 1 further includes the encapsulation layer 16 located between the light-emitting unit 13 and the electrically conductive layer 15 and between the shielding layer 14 and the electrically conductive layer 15, the encapsulation layer 16 may include a first encapsulation layer 161, a second encapsulation layer 162, and a third encapsulation layer 163 stacked along the direction away from the substrate 11; the material of the first encapsulation layer 161 and the third encapsulation layer 163 may be an inorganic material, which has strong ability to isolate water and oxygen, and the material of the second encapsulation layer 162 may be an organic material, which has great fluidity.

As shown in FIG. 4, the non-display area NA further includes the levelling area NA1 along a direction away from the display area AA, which is configured to level the second encapsulation layer 162. The non-display area NA may further include a blocking area NA2 located at a side of the levelling area NA1 away from the display area AA, and the blocking area NA2 includes a dam 18 configured to block the second encapsulation layer 162.

Specifically, a size D of the levelling area NA1 along a direction from the display area AA towards the non-display area NA is greater than 50 microns, so that sufficient space can be provided for levelling the second encapsulation layer 162, and the flatness at a side of the second encapsulation layer 162 away from the substrate 11 is improved.

In the above implementation, a thickness of the encapsulation layer 16 may be gradually reduced along a direction from the display area AA towards the levelling area NA1, wherein the thickness refers to a size along a direction perpendicular to a plane where the substrate 11 is located, that is, along a thickness direction of the substrate 11. A portion of the encapsulation layer 16 located above the second portion 122 is also gradually thinned along the direction from the display area AA towards the levelling area NA1, in particular, the encapsulation layer 16 located above the second portion 122 away from the display area AA is thinned more significantly, and under this condition, by forming the second section 1322 of the light-emitting material layer 1320 and the second sub-portion 142 of the shielding layer 14 at the side of the second portion 122 away from the substrate 11, the first encapsulation layer 161 can be arranged continuously at the side of the second portion 122 away from the substrate, and the encapsulation layer 16 may be in contact with a side surface of the isolation structure 12 away from the second opening 1221, so that a side surface of the second portion 122 away from the substrate 11 is packet for encapsulation, and the probability of exposure due to encapsulation failure of the second portion 122 is reduced, so as to prevent the shielding failure of the second portion 122 and improve the reliability of the shielding effect of the second portion 122.

In a possible implementation, the encapsulation layer 16 is in contact with a side surface of the isolation structure 12 facing the second opening 1221, so that the encapsulation layer 16 overlaps the isolation structure 12 while covering the first sub-portion 141 to achieve good encapsulation effect.

In a possible implementation, the shielding layer 14 includes a first sub-portion 141 located in the second opening 1221 and a second sub-portion 142 located at a side of the second portion 122 away from the substrate 11, and the encapsulation layer 16 is in contact with a side of the second sub-portion 142 away from the substrate 11; therefore, overhanging of the encapsulation layer 16 can be avoided, and the probability of water and oxygen entering between the encapsulation layer 16 and the underlying film layer from the location of the overhanging is reduced, so as to improve the encapsulation yield and further improve the shielding effect, thereby reducing the probability of shielding failure due to the first sub-portion 141 being eroded by water and oxygen.

In a possible implementation, the electrically conductive layer 15 includes a touch control layer including a touch control wiring 151 located in the non-display area NA, and an orthographic projection of the touch control wiring 151 on the substrate 11 is located within an orthographic projection of the shielding layer 14 on the substrate 11, or within an orthographic projection of the isolation structure 12 on the substrate 11.

In the above implementation, the electrically conductive layer 15 may include the touch control layer to achieve touch control function, or may include other film layers, which is not specifically limited in the present application. The touch control layer includes the touch control wiring 151 located in the non-display area NA, the shielding layer 14 is in contact with the second portion 122 to form a continuous shielding surface, the orthographic projection of the touch control wiring 151 on the substrate 11 is located within the orthographic projection of the shielding layer 14 on the substrate 11, or within the orthographic projection of the isolation structure 12 on the substrate 11, so as to achieve shielding between the touch control wiring 151 and a film layer, which is electrically conductive, in the substrate 11.

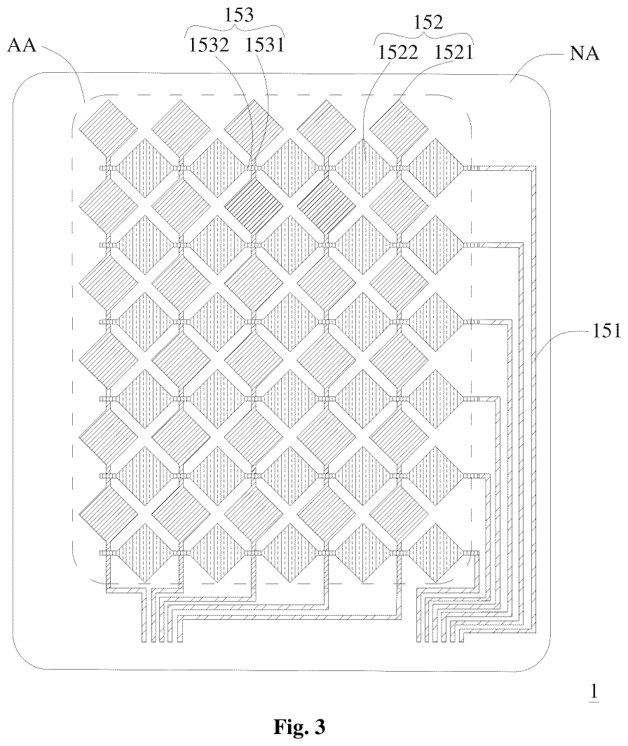

Specifically, as shown in FIG. 3, the touch control layer further includes a touch control electrode 152 and a connection line 153 located in the display area AA, the touch control electrode 152 may include a first touch control electrode 1521 and a second touch control electrode 1522, the connection line 153 may include a first connection line 1531 and a second connection line 1532, the touch control layer may include a first electrically conductive layer and a second electrically conductive layer stacked along the direction away from the substrate 11, and the first electrically conductive layer and the second electrically conductive layer are insulated from each other; the first electrically conductive layer includes the first connection line 1531, the second electrically conductive layer includes the touch control electrode 152 and the second connection line 1532, the first touch control electrodes 1521 are distributed in rows and columns, at least a portion of adjacent first touch control electrodes 1521 along a column direction are electrically connected through the first connection line 1531, the second touch control electrodes 1522 are arranged in rows and columns, at least a portion of adjacent second touch control electrodes 1522 along a row direction are electrically connected through the second connection line 1532, and the connection line 153 or the touch control electrode 152 are directly connected to the touch control wiring 151.

In a possible implementation, the substrate 11 includes a metal layer including a metal wiring located in the non-display area NA, the metal wiring includes the signal line 111, and the signal in the signal line 111 is different from the signal in the touch control wiring 151. An orthographic projection of the touch control wiring 151 on the metal layer at least partially overlaps the metal wiring. Interference is more likely to occur at the overlapping location, and shielding for the signals within the touch control wiring 151 and the metal wiring may be achieved through the shielding layer 14 and the isolation structure 12 to reduce the interference, thereby improving the performance of the display panel 1.

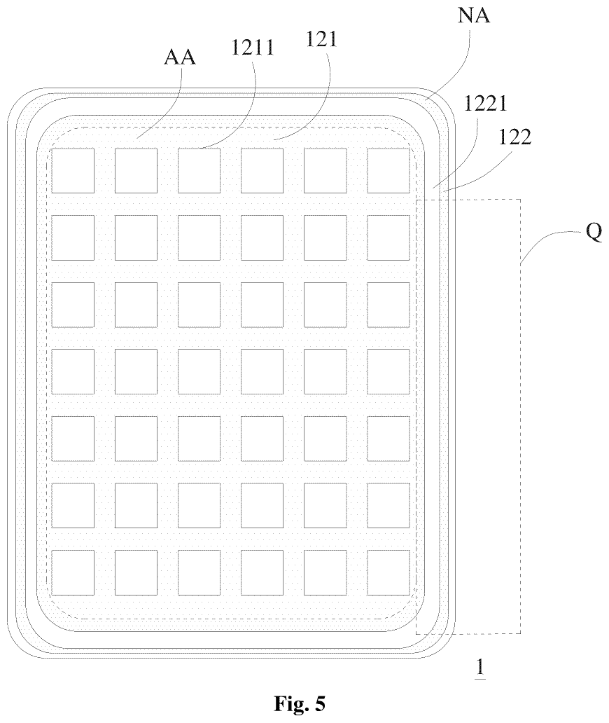

In a possible implementation, as shown in FIG. 5, the non-display area NA includes at least one second opening 1221 arranged surrounding the display area AA.

Specifically, the non-display area NA may include only one second opening 1221 arranged surrounding the display area AA; or the non-display area NA includes a plurality of second openings 1221 each arranged surrounding the display area AA, and the plurality of second openings 1221 are nested in sequence (not shown).

The second opening 1221 is arranged surrounding the display area AA, so that the area of the second opening 1221 can be increased to ensure the flatness of film layers under the touch control wiring 151 and reduce the risk of breaking of the touch control wiring 151.

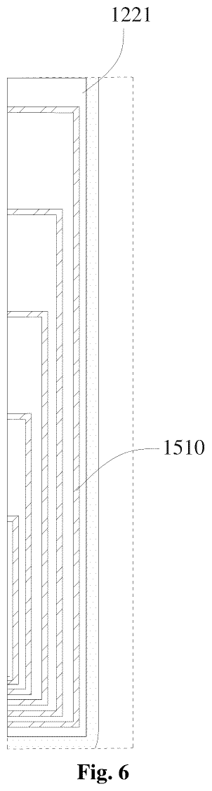

In a possible implementation, as shown in FIG. 5 and FIG. 6, the touch control wiring 151 includes a wiring segment 1510 extending surrounding a portion of the display area AA, and an orthographic projection of the wiring segment 1510 on the substrate 11 is located within an orthographic projection of the second opening 1221 on the substrate 11.

Specifically, the edge of the display area AA may be a rectangle in shape, the wiring segment 1510 may include a portion extending along a row direction and a portion extending along a column direction of the distribution directions of the touch electrodes 152, and the row direction and the column direction are parallel to two side edges of the rectangle, respectively.

The wiring segment 1510 extends surrounding a portion of the display area AA, that is, the wiring segment 1510 extends along the same direction as the second opening 1221, so that an orthographic projection of the wiring segment 1510 on the substrate 11 may be located within the orthographic projection of the second opening 1221 on the substrate 11, the first sub-portion 141 of the shielding layer 14 is arranged within the second opening 1221, and the first sub-portion 141 can shield the wiring segment 1510 from the signal line 111 within the substrate 11. Moreover, the wiring segment 1510 does not pass through the edge of the second opening 1221, so that film layers under the wiring segment 1510 have good flatness, thereby reducing the risk of short circuit and open circuit of the touch control wiring 151 and improving the reliability and credibility of the touch control wiring 151. In addition, the film layers under the wiring segment 1510 are the same, which reduces the difference between different wiring segments 1510 and facilitates improving transmission quality of the touch control signal.

Specifically, the orthographic projection of the wiring segment 1510 on the substrate 11 is located within the orthographic projection of the shielding layer 14 on the substrate 11. Specifically, the orthographic projection of the wiring segment 1510 on the substrate 11 is located within an orthographic projection of the first sub-portion 141 on the substrate 11. Accordingly, the wiring segment 1510 does not pass over the edge of the isolation structure 12, and only passes over the first sub-portion 141, so that the film layers under the wiring segment 1510 have good flatness, and the first sub-portion 141 can achieve a good shielding effect.

In a possible implementation, as shown in FIG. 2, the touch control wiring 151 includes a wiring segment 1510 extending surrounding a portion of the display area AA, a portion of an orthographic projection of the wiring segment 1510 on the substrate 11 is located within the orthographic projection of the second opening 1221 on the substrate 11, a portion of the orthographic projection of the wiring segment 1510 on the substrate 11 is located within an orthographic projection of the second portion 122 on the substrate 11, and an edge of the orthographic projection of the second portion 122 on the substrate 11 does not overlap the orthographic projection of the wiring segment 1510 on the substrate 11.

In the above implementation, a portion of the orthographic projection of the wiring segment 1510 on the substrate 11 is located within the orthographic projection of the second opening 1221 on the substrate 11, and a portion of the orthographic projection of the wiring segment 1510 on the substrate 11 is located within the orthographic projection of the second portion 122 on the substrate 11, that is, a portion of the wiring segment 1510 is located above the second opening 1221 and a portion of the wiring segment 1510 is located above the second portion 122, all of which can ensure the flatness of the film layers under the wiring segment 1510, as long as it is ensured that the wiring segment 1510 is not located above the edge of the second portion 122, that is, above the edge of the second opening 1221. The edge of the second portion 122 is a transition area between the second portion 122 and the second opening 1221 and has a segment difference, which is not beneficial for ensuring the flatness.

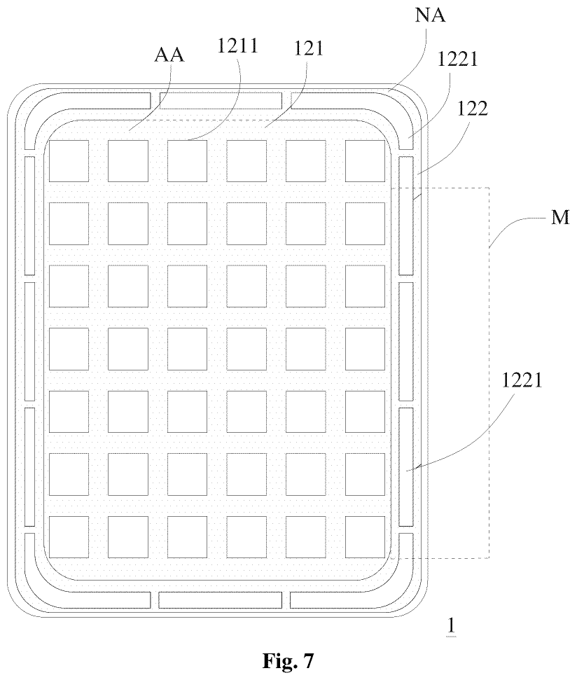

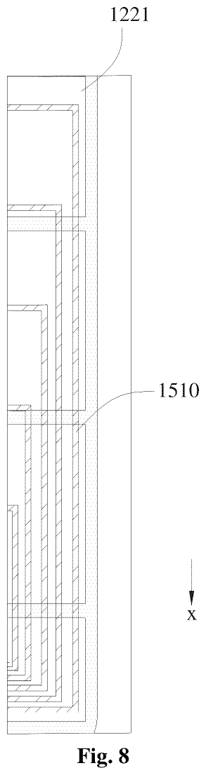

In a possible implementation, as shown in FIG. 7 and FIG. 8, the non-display area NA includes a plurality of second openings 1221 distributed along a periphery of the display area AA. The touch control wiring 151 includes a first segment extending along a first direction, an orthographic projection of a portion of the plurality of second openings 1221 on the substrate 11 is a rectangle in shape, and sizes of a portion of the second openings 1221 along the first direction are the same. Accordingly, it can be ensured that the widths of the second portions 122 between the second openings 1221 through which the various first segments pass is relatively uniform, which facilitates ensuring the uniformity of the film layers under the touch control wiring 151 and reducing the difference between different touch control wirings 151, thereby ensuring touch control quality.

In the above implementation, the edge of the display area AA may be a rectangle in shape and include a long side and a short side, and the first direction may be parallel to a long side.

In the above implementation, the plurality of second openings 1221 are uniformly distributed in the non-display area NA, so that difference between the various first segments can be reduced.

In the above implementation, an area of an orthographic projection of at least a portion of the second openings 1221 on the substrate 11 is greater than an area of an orthographic projection of the first opening 1211 on the substrate 11; the area of the second opening 1221 is set to be relatively great, so that the flatness of the film layers under the touch control wiring 151 can be increased to improve the yield of the touch control wiring 151.

It should be noted that the first opening 1211 is configured to accommodate the light-emitting unit 13, and for the light-emitting units 13 of different colors, the areas of the orthographic projections of the first openings 1211 corresponding to the light-emitting units 13 of different colors on the substrate 11 may be the same or different. However, the area of the orthographic projection of at least a portion of the second openings 1221 on the substrate 11 needs to be greater than the area of the orthographic projection of the largest first opening 1211 on the substrate 11, thereby increasing the flatness of the film layers under the touch control wiring 151.

In the above implementation, an extension direction of a portion of the second portion 122 located between two of the second openings 1221 adjacent along the periphery of the display area AA intersects with an extension direction of the touch control wiring 151, an orthographic projection of the portion of the second portion 122 located between two of the second openings 1221 adjacent along the periphery of the display area AA on the substrate 11 is a first projection, and the first projection partially overlaps the orthographic projection of the touch control wiring 151 on the substrate 11. That is, one touch control wiring 151 passes over a plurality of second openings 1221 along its length direction.

In a possible implementation, as shown in FIG. 2 and FIG. 4, the isolation structure 12 includes a first isolation portion 123 and a second isolation portion 124, the second isolation portion 124 is located at a side of the first isolation portion 123 away from the substrate 11, and an orthographic projection of the second isolation portion 124 on the substrate 11 covers an orthographic projection of the first isolation portion 123 on the substrate 11.

In the above implementation, the first portion 121 and the second portion 122 of the isolation portion may each include the first isolation portion 123 and the second isolation portion 124.

In the above implementation, a step portion is formed between the first isolation portion 123 and the second isolation portion 124, and the light-emitting functional layer 132 and the second electrode 133 may be partitioned in the display area AA, so that the light-emitting functional layers 132 in adjacent light-emitting units 13 are independent from each other, and the second electrodes 133 in the adjacent light-emitting units 13 are also independent from each other. The light-emitting material layer 1320 manufactured in the same layer as the light-emitting functional layer 132 may be formed while the light-emitting functional layer 132 is formed, and the light-emitting material layer 1320 and the shielding layer 14 may be partitioned in the non-display area NA.

In the above implementation, the second electrodes 133 are independent from each other, and thus it is difficult to supply power to each of the second electrodes 133, and at least a portion of the second electrodes 133 are electrically connected through the first portion 121 of the isolation structure 12 and then powered up synchronously, so that the various second electrodes 133 can be powered up synchronously, and thus the number of the power supply lines is reduced, and the manufacturing process is simplified. Moreover, since the material of the second electrode 133 is usually a magnesium-silver alloy, while the material of the isolation structure 12 includes aluminum which has a smaller resistance than that of the magnesium-silver alloy, the resistance of the connection for the isolation structure 12 and the second electrodes 133 is smaller than that of the conventional whole-surface second electrode 133, which can reduce the power consumption of the display panel 1, so that the difference caused by attenuation (IR-DROP) in the signal transmission between a near driving terminal and a remote driving terminal due to a relatively great resistance can be reduced, thereby improving the display uniformity of the display panel.

In the above implementation, the shielding layer 14 forms, after being partitioned by the second portion 122, the first sub-portion 141 located within the second opening 1221 and the second sub-portion 142 located at the side of the second section 1322 away from the second portion 122, a plurality of second sub-portions 142 can be electrically connected through the electrical connection between the second portion 122 and the second sub-portion 142s, which facilitates synchronous powering up for the second portion 122 and the second sub-portion 142 to form a sealed film layer and achieve shielding function.

In a possible implementation, as shown in FIG. 2 and FIG. 4, the display panel 1 further includes a pixel definition layer 17, a portion of the pixel definition layer 17 located in the display area AA is formed at a side of the first electrode 131 away from the substrate 11, a portion of the pixel definition layer 17 located in the non-display area NA is in contact with the substrate 11, the pixel definition layer 17 includes a pixel definition portion 171 and a plurality of pixel openings 172 located in the display area AA, and the pixel opening 172 is arranged opposite to the first opening 1211.

In the above implementation, a portion of the pixel definition layer 17 located in the display area AA covers the edge of the first electrode 131, so as to protect the first electrode 131 and insulate the adjacent first electrodes 131, to reduce the interference between the adjacent first electrodes 131. The portion of the pixel definition layer 17 located in the display area AA includes at least a first pixel opening 172, a second pixel opening 172, and a third pixel opening 172. Specifically, if the display panel 1 includes the light-emitting units 13 of three colors, the first pixel opening 172 is configured to form a red light-emitting unit 13, the second pixel opening 172 is configured to form a green light-emitting unit 13, and the third pixel opening 172 is configured to form a blue light-emitting unit 13, and if the display panel 1 further includes a white light-emitting unit 13, the pixel definition layer 17 may further include a fourth pixel opening 172 configured to form the white light-emitting unit 13.

The portion of the pixel definition layer 17 located in the non-display area NA is in contact with the substrate 11, so as to provide a flat surface for subsequent film layers, which facilitates improving the reliability of the touch control wiring 151 and reducing the occurrence of open circuit and short circuit.

If the display panel 1 includes the isolation structure 12, the light-emitting units 13 of individual colors may be manufactured as a whole layer and then patterned, thereby omitting the use of the mask to reduce the cost. The light-emitting units 13 of different colors are manufactured in different steps, and in the patterning of the light-emitting unit 13 which is manufactured later, the isolation structure 12 may provide isolation, so as to improve the yield of the patterning process and reduce the effect of the patterning on the yield of the light-emitting unit 13. In the manufacturing of the light-emitting unit 13 of the last color, portions of the light-emitting functional layer 132 and the second electrode 133 located in the non-display area NA may be maintained to form the light-emitting material layer 1320 and the shielding layer 14, so that the light-emitting material layer 1320 and the shielding layer 14 can be manufactured using the original manufacturing process, while no new material is added in the manufacturing process, thereby reducing the manufacturing cost.

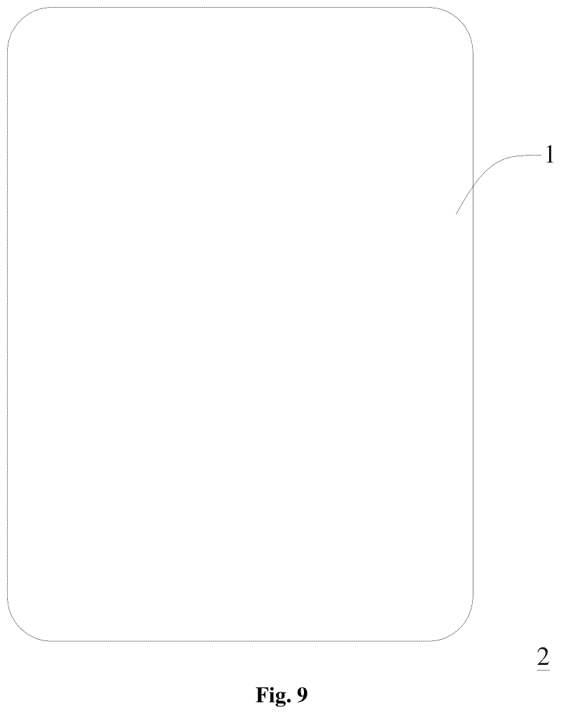

The present application further provides a display apparatus 2, as shown in FIG. 9, which includes any one of the display panels 1 according to the above implementations of the present application. In the display apparatus 2, good shielding effect can be achieved for the touch control wiring 151 and a portion of a signal line within the substrate 11 located in the non-display area NA, and thus the interference between the touch control wiring 151 and the portion of the signal line within the substrate 11 located in the non-display area NA is reduced, and the yield of the display apparatus 2 is improved.

The display apparatus 2 may be a mobile terminal such as a mobile phone and a notebook computer, or a fixed terminal such as a television and a computer display, or a wearable device such as a watch, which is not particularly limited in the present application.

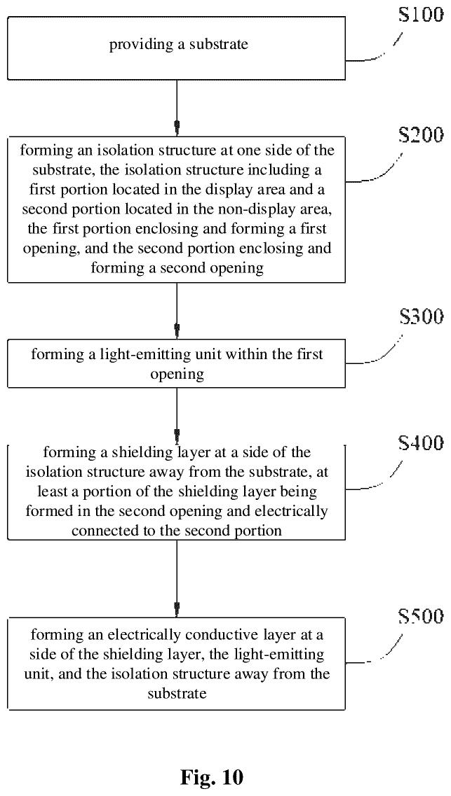

The present application further provides a method for manufacturing a display panel having a display area and a non-display area arranged surrounding at least a portion of the display area, as shown in FIG. 10, the method includes:
S100: providing a substrate 11;
S200: forming an isolation structure 12 at one side of the substrate 11, the isolation structure 12 including a first portion 121 located in the display area AA and a second portion 122 located in the non-display area NA, the first portion 121 encircling a first opening 1211, and the second portion 122 encircling a second opening 1221;
S300: forming a light-emitting unit 13 within the first opening;
S400: forming a shielding layer 14 at a side of the isolation structure 12 away from the substrate 11, at least a portion of the shielding layer 14 being formed in the second opening 1221 and electrically connected to the second portion 122; and
S500: forming an electrically conductive layer at a side of the shielding layer 14, the light-emitting unit 13, and the isolation structure 12 away from the substrate 11.

In the display panel manufactured using the method according to the present application, the second portion 122 in the isolation structure located within the non-display area NA and the shielding layer 14 may form a continuous film layer, so as to achieve the mutual shielding between the portion of the electrically conductive layer 15 located in the non-display area NA and the signal line 111 in the substrate 11 located within the non-display area NA, and reduce the mutual interference between the signal within the portion of the electrically conductive layer 15 located in the non-display area NA and the signal within the signal line 111 in the substrate 11, so that the yield of the display panel 1 is improved. Accordingly, the user experience can be further improved.

The above embodiments of the present application do not exhaustively describe all the details and do not limit the present invention to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims, along with their full scope and equivalents.

What is claimed is:

1. A display panel having a display area and a non-display area arranged surrounding at least a portion of the display area, the display panel comprising:
a substrate;
an isolation structure formed at one side of the substrate and comprising a first portion located in the display area and a second portion located in the non-display area, the first portion encircling a first opening, and the second portion encircling a second opening;
a light-emitting unit formed at one side of the substrate and located in the first opening;
a shielding layer at least partially formed in the second opening and electrically connected to the second portion; and
an electrically conductive layer formed at a side of the shielding layer, the light-emitting unit, and the isolation structure being away from the substrate.

2. The display panel according to claim 1, wherein the light-emitting unit comprises a first electrode, a light-emitting functional layer, and a second electrode stacked along a direction away from the substrate, and the shielding layer is manufactured in the same layer as the second electrode;
the shielding layer comprises a first sub-portion located in the second opening and a second sub-portion located at a side of the second portion away from the substrate; and
the display panel further comprises a light-emitting material layer, the light-emitting material layer is arranged in the same layer as the light-emitting functional layer and comprises a first section located in the second opening and a second section located at a side of the second portion away from the substrate.

3. The display panel according to claim 1, wherein the electrically conductive layer comprises a touch control layer comprising a touch control wiring located in the non-display area, and an orthographic projection of the touch control wiring on the substrate is located within an orthographic projection of the shielding layer on the substrate, or within an orthographic projection of the isolation structure on the substrate.

4. The display panel according to claim 3, wherein the substrate comprises a metal layer comprising a metal wiring located in the non-display area, and an orthographic projection of the touch control wiring on the metal layer at least partially overlaps the metal wiring.

5. The display panel according to claim 3, wherein the non-display area comprises at least a second opening, and the at least a second opening is arranged surrounding the display area.

6. The display panel according to claim 5, wherein the touch control wiring comprises a wiring segment extending surrounding a portion of the display area, and an orthographic projection of the wiring segment on the substrate is located within an orthographic projection of the second opening on the substrate; and
the orthographic projection of the wiring segment on the substrate is located within the orthographic projection of the shielding layer on the substrate.

7. The display panel of claim 3, wherein the touch control wiring comprises a wiring segment extending surrounding a portion of the display area, a portion of an orthographic projection of the wiring segment on the substrate is located within an orthographic projection of the second opening on the substrate, a portion of the orthographic projection of the wiring segment on the substrate is located within an orthographic projection of the second portion on the substrate, and an edge of the orthographic projection of the second portion on the substrate does not overlap the orthographic projection of the wiring segment on the substrate.

8. The display panel according to claim 3, wherein the non-display area comprises a plurality of second openings, and the plurality of second openings are distributed along a periphery of the display area.

9. The display panel according to claim 8, wherein
the plurality of second openings are uniformly distributed in the non-display area.

10. The display panel according to claim 8, wherein
an area of an orthographic projection of at least a portion of the second openings on the substrate is greater than an area of an orthographic projection of the first opening on the substrate.

11. The display panel according to claim 8, wherein
an extension direction of a portion of the second portion located between two of the second openings adjacent along the periphery of the display area intersects with an extension direction of the touch control wiring.

12. The display panel according to claim 8, wherein an orthographic projection of a portion of the second portion located between two of the second openings adjacent along the periphery of the display area on the substrate is a first projection, and the first projection partially overlaps the orthographic projection of the touch control wiring on the substrate.

13. The display panel according to claim 8, wherein
the touch control wiring comprises a first segment extending along a first direction, an orthographic projection of a portion of the second openings on the substrate is a rectangle in shape, and sizes of a portion of the plurality of second openings along the first direction are same.

14. The display panel according to claim 1, wherein the non-display area further comprises a levelling area located at a side of the second portion away from the display area, the display panel further comprises an encapsulation layer located at a side of the shielding layer and the light-emitting unit away from the substrate and between the substrate and the electrically conductive layer, and along a direction perpendicular to a plane where the substrate is located, a thickness of a portion of the encapsulation layer within the levelling area is less than a thickness of a portion of the encapsulation layer located within the display area and less than a thickness of a portion of the encapsulation layer located between the levelling area and the display area;
the encapsulation layer is in contact with a side surface of the isolation structure facing the second opening.

15. The display panel according to claim 14, wherein
the shielding layer comprises a first sub-portion located in the second opening and a second sub-portion located at a side of the second portion away from the substrate, and the encapsulation layer is in contact with a side of the second sub-portion away from the substrate; and
the encapsulation layer is in contact with a side surface of the isolation structure away from the second opening.

16. The display panel according to claim 1, wherein the isolation structure comprises a first isolation portion and a second isolation portion, the second isolation portion is located at a side of the first isolation portion away from the substrate, and an orthographic projection of the second isolation portion on the substrate covers an orthographic projection of the first isolation portion on the substrate.

17. The display panel according to claim 2, wherein
the display panel further comprises a pixel definition layer, a portion of the pixel definition layer located in the display area is formed at a side of the first electrode away from the substrate, a portion of the pixel definition layer located in the non-display area is in contact with the substrate, the pixel definition layer comprises a pixel definition portion and a plurality of pixel openings located in the display area, and the pixel opening is arranged opposite to the first opening.

18. A method for manufacturing a display panel having a display area and a non-display area arranged surrounding at least a portion of the display area, the method comprising:
providing a substrate;
forming an isolation structure at one side of the substrate, the isolation structure comprising a first portion located in the display area and a second portion located in the non-display area, the first portion encircling a first opening, and the second portion encircling a second opening;
forming a light-emitting unit within the first opening;
forming a shielding layer at a side of the isolation structure away from the substrate, at least a portion of the shielding layer being formed in the second opening and electrically connected to the second portion; and
forming an electrically conductive layer at a side of the shielding layer, the light-emitting unit, and the isolation structure away from the substrate.

19. A display panel, having a display area and a non-display area arranged surrounding at least a portion of the display area, the display panel comprising:
a substrate comprising a circuit structure;
a light-emitting unit formed at one side of the substrate and located in the display area;
an electrically conductive layer formed at a side of the light-emitting unit away from the substrate; and
a shielding structure arranged between the electrically conductive layer and the circuit structure of the substrate and at least partially located in the non-display area, and an orthographic projection of the shielding structure on the substrate covering an orthographic projection of the electrically conductive layer on the substrate.

20. The display panel according to claim 19, wherein the shielding structure comprises an isolation structure formed at one side of the substrate, the isolation structure comprises a first portion located in the display area and a second portion located in the non-display area, the first portion encircles a first opening, and the light-emitting unit is located in the first opening;
an orthographic projection of the second portion on the substrate overlaps an orthographic projection of the electrically conductive layer on the substrate.

21. The display panel according to claim 20, wherein
within the non-display area, the orthographic projection of the second portion on the substrate completely covers the orthographic projection of the electrically conductive layer on the substrate;
at least a portion of film layers of the first portion and at least a portion of film layers of the second portion have a same material and are manufactured in a same layer;
the second portion is arranged surrounding the display area in the non-display area.

22. The display panel according to claim 19, wherein the light-emitting unit comprises a first electrode, a light-emitting functional layer, and a second electrode stacked along a direction away from the substrate, and the shielding structure comprises a shielding layer manufactured in the same layer as the second electrode or the first electrode;
an orthographic projection of the shielding layer on the substrate overlaps the orthographic projection of the electrically conductive layer on the substrate; and
in the non-display area, the orthographic projection of the shielding layer on the substrate completely covers the orthographic projection of the electrically conductive layer on the substrate.

23. The display panel according to claim 20, wherein the shielding structure comprises an isolation structure and a shielding layer formed at one side of the substrate, the isolation structure comprises a first portion located in the display area and a second portion located in the non-display area, the first portion encircles a first opening, and the second portion encircles a second opening;
the light-emitting unit is located in the first opening, the shielding layer comprises a first sub-portion located in the second opening, and the first sub-portion is electrically connected to the second portion;
the shielding layer further comprises a second sub-portion located at a side of the second portion away from the substrate;
the light-emitting unit comprises a first electrode, a light-emitting functional layer, and a second electrode stacked along a direction away from the substrate, and the shielding layer is manufactured in the same layer as the second electrode or the first electrode; and
the display panel further comprises a light-emitting material layer, the light-emitting material layer is arranged in the same layer as at least a portion of the light-emitting functional layer and comprises a first section located in the second opening and a second section located at a side of the second portion away from the substrate; and
at least a portion of film layers of the first portion and at least a portion of film layers of the second portion have a same material and are manufactured in a same layer.

24. The display panel according to claim 23, wherein the electrically conductive layer comprises a touch control layer comprising a touch control wiring located in the non-display area, and an orthographic projection of the touch control wiring on the substrate is located within an orthographic projection of the shielding layer on the substrate, or within an orthographic projection of the isolation structure on the substrate; and
the substrate comprises a metal layer comprising a metal wiring located in the non-display area, and an orthographic projection of the touch control wiring on the metal layer at least partially overlaps the metal wiring,
the second opening is arranged surrounding the display area.

25. The display panel according to claim 23, wherein the non-display area further comprises a levelling area located at a side of the second portion away from the display area, the display panel further comprises an encapsulation layer located at a side of the shielding layer and the light-emitting unit away from the substrate and between the substrate and the electrically conductive layer, and along a direction perpendicular to a plane where the substrate is located, a thickness of a portion of the encapsulation layer within the levelling area is less than a thickness of a portion of the encapsulation layer located within the display area and less than a thickness of a portion of the encapsulation layer located between the levelling area and the display area;
the encapsulation layer is in contact with a side surface of the isolation structure facing the second opening;
the shielding layer comprises a first sub-portion located in the second opening and a second sub-portion located at a side of the second portion away from the substrate, and the encapsulation layer is in contact with a side of the second sub-portion away from the substrate;
the encapsulation layer is in contact with a side surface of the isolation structure away from the second opening; and
a size of the levelling area along a direction from the display area towards the non-display area is greater than 50 microns.

26. The display panel according to claim 23, wherein the isolation structure comprises a first isolation portion and a second isolation portion, the second isolation portion is located at a side of the first isolation portion away from the substrate, and an orthographic projection of the second isolation portion on the substrate covers an orthographic projection of the first isolation portion on the substrate; and
the display panel further comprises a pixel definition layer, a portion of the pixel definition layer located in the display area is formed at a side of the first electrode away from the substrate, a portion of the pixel definition layer located in the non-display area is in contact with the substrate, the pixel definition layer comprises a pixel definition portion and a plurality of pixel openings located in the display area, and the pixel opening is arranged opposite to the first opening.
